(19) United States
(12) Patent Application Publication
(10) Pub. No.: US 2026/0292989 A1
(43) Pub. Date: Sep. 24, 2026

(54) BALL GRID ARRAY PACKAGE

(71) Applicant: LG INNOTEK CO., LTD., Seoul (KR)

(72) Inventors: Seong Su EOM, Seoul (KR); Jee Hee LIM, Seoul (KR); Jun Phill EOM, Seoul (KR); Hee Jung LEE, Seoul (KR); Do Youb KWON, Seoul (KR)

(73) Assignee: LG INNOTEK CO., LTD., Seoul (KR)

(21) Appl. No.: 19/165,382

(22) PCT Filed: Mar. 13, 2024
(86) PCT No.: PCT/KR2024/003228

§ 371 Date: Sep. 15, 2025

(30) Foreign Application Priority Data
Mar. 15, 2023 (KR) 10-2023-0033881
Mar. 17, 2023 (KR) 10-2023-0034935
Apr. 12, 2023 (KR) 10-2023-0048134

(51) Int. Cl. H05K 1/14; H05K 1/181; H05K 3/36

(52) U.S. Cl. CPC H05K 1/144; H05K 3/368; H05K 1/181; H05K 2201/0166; H05K 2201/041; H05K 2203/041

(57) ABSTRACT

A ball grid array package according to an embodiment of the present invention comprises: a first circuit board; a second circuit board disposed above the first circuit board; a first solder ball and a second solder ball disposed between the first circuit board and the second circuit board so as to be spaced apart from each other; a first adhesive disposed between the first circuit board and the second circuit board so as to extend from the upper surface of the first circuit board to the lower surface of the second circuit board along a first side surface of the first solder ball; and a second adhesive disposed between the first circuit board and the second circuit board so as to extend from the upper surface of the first circuit board to the lower surface of the second circuit board along a second side surface of the second solder ball. The first side surface of the first solder ball and the second side surface of the second solder ball are disposed to face each other. The first adhesive and the second adhesive form a channel area between the first circuit board and the second circuit board. The area of the channel area corresponds to 30-70% of the area of spacing between the first side surface of the first solder ball and the second side surface of the second solder ball.

### TECHNICAL FIELD

Embodiments of the present invention relate to a ball grid array package, and more particularly, to filling a ball grid array package.

### BACKGROUND ART

A ball grid array (BGA) package is a type of surface mount package for integrated circuits and is used in various fields such as vehicles, communications, and cameras.

A ball grid array package may have high density and high thermal conductivity and have excellent electrical performance due to low inductance.

A typical ball grid array package has a form in which solder balls of BGA chip are bonded onto a circuit board. When ball grid array packages are applied to vehicles or communication devices, cracks around the solder balls due to thermal shock caused by temperature changes or shock caused by vibrations may occur.

To solve these problems, an SMT process in which a BGA chip is mounted on pads of a circuit board and then reflowed, and an underfill process in which underfill is performed after cleaning may be performed sequentially.

However, due to the miniaturization and high integration of integrated circuit (IC) chips and the outgassing of underfill materials, fine and non-uniform voids may be formed between solder balls, which may affect the reliability of ball grid array packages.

In addition, when a reflow process is performed in consideration of the melting point of a solder ball, warpage may occur due to a difference in thermal stress between a circuit board and a BGA chip, which may cause cracks in the solder ball.

In addition, there is a problem that manufacturing time and costs increase according to an underfill process.

### DETAILED DESCRIPTION OF INVENTION

### Technical Problem

The technical object achieved by the present invention is to provide a highly reliable ball grid array package.

### Technical Solution

A ball grid array package according to one embodiment of the present invention includes a first circuit board, a second circuit board disposed on the first circuit board, a first solder ball and a second solder ball disposed to be spaced apart from each other between the first circuit board and the second circuit board, a first bonding agent disposed along a first side surface of the first solder ball from an upper surface of the first circuit board to a lower surface of the second circuit board between the first circuit board and the second circuit board, and a second bonding agent disposed along a second side surface of the second solder ball from the upper surface of the first circuit board to the lower surface of the second circuit board between the first circuit board and the second circuit board, wherein the first side surface of the first solder ball and the second side surface of the second solder ball are disposed to face each other, the first bonding agent and the second bonding agent form a channel area between the first circuit board and the second circuit board, and an area of the channel area is in a range of 30% to 70% of an area of a separation area between the first side surface of the first solder ball and the second side surface of the second solder ball.

The area of the channel area may be in a range of 50% to 70% of the area of the separation area between the first side surface of the first solder ball and the second side surface of the second solder ball.

A maximum width of the channel area between the first bonding agent and the second bonding agent may be 50% or more of a diameter of at least one of the first solder ball and the second solder ball.

At least one of a horizontal thickness of the first bonding agent on the first side surface of the first solder ball and a horizontal thickness of the second bonding agent on the second side surface of the second solder ball on a center line between the first circuit board and the second circuit board may be in a range of 10% to 50% of at least one of a diameter of the first solder ball and a diameter of the second solder ball.

At least one of a horizontal thickness of the first bonding agent on the first side surface of the first solder ball and a horizontal thickness of the second bonding agent on the second side surface of the second solder ball on a center line between the first circuit board and the second circuit board may be in a range of 5 μm to 20 μm.

The first bonding agent and the second bonding agent may meet each other on at least one of the upper surface of the first circuit board and the lower surface of the second circuit board.

At least one of the first bonding agent and the second bonding agent may include an area in which a thickness in a direction parallel to the first circuit board or the second circuit board decreases and then increases again in a direction from the first circuit board to the second circuit board.

The first bonding agent and the second bonding agent may include an epoxy resin, a curing agent having a flux function, and an inorganic filler, and the curing agent having a flux function may include an anhydride and abietic acid.

The curing agent having a flux function may include hexahydromethylphthalic anhydride and rosin.

The epoxy resin may include a naphthalene-based epoxy resin.

The inorganic filler may include silica and carbon black.

A ball grid array package according to another embodiment of the present invention includes a first circuit board, a second circuit board disposed on the first circuit board, a plurality of solder balls disposed to be spaced apart from each other between the first circuit board and the second circuit board, and a bonding agent disposed along side surfaces of the plurality of solder balls from an upper surface of the first circuit board to a lower surface of the second circuit board between the first circuit board and the second circuit board, wherein a channel surrounded by the bonding agent is formed between the first circuit board and the second circuit board, and an area of the channel is in a range of 30% to 70% of an area of a separation area between the plurality of solder balls.

A ball grid array package according to still another embodiment of the present invention includes a first circuit board, a second circuit board disposed on the first circuit board, a plurality of solder balls disposed to be spaced apart from each other between the first circuit board and the second circuit board, and a filling member disposed on the first circuit board along an edge of the second circuit board, wherein a surface of the filling member has a convex shape with respect to an extension line from an edge of the filling member disposed on the upper surface of the first circuit board to an edge of a lower surface of the second circuit board.

At least a portion of the filling member may be disposed on the extension line.

The extension line may have an angle of 45° to 90° with respect to the upper surface of the first circuit board.

The ball grid array package may include a section in which the angle between the surface of the filling member and the upper surface of the first circuit board decreases in a direction from the first circuit board to the second circuit board.

At least a portion of the filling member may be disposed on a side surface of the second circuit board.

With respect to the upper surface of the first circuit board, a maximum height of the filling member may be greater than that of the lower surface of the second circuit board.

The ball grid array package may further include a bonding agent disposed along side surfaces of the plurality of solder balls from the upper surface of the first circuit board between the first circuit board and the second circuit board, a channel surrounded by at least some of the upper surface of the first circuit board, the bonding agent, the side surfaces of the plurality of solder balls, and the lower surface of the second circuit board may be formed between the first circuit board and the second circuit board, and an area of the above channel may be in a range of 30% to 70% of an area of a separation area between the plurality of solder balls.

The bonding agent may be disposed to extend to the lower surface of the second circuit board along the side surfaces of the plurality of solder balls, and an area of the bonding agent in contact with the upper surface of the first circuit board may be greater than or equal to an area of the bonding agent in contact with the lower surface of the second circuit board.

A thickness of the bonding agent in a direction parallel to the first circuit board may decrease in a direction from the upper surface of the first circuit board to the side surface of the solder ball.

The bonding agent may include an epoxy resin, a curing agent having a flux function, and an inorganic filler, and the curing agent having a flux function may include an anhydride and abietic acid.

A ball grid array package according to yet another embodiment of the present invention includes a first circuit board in which a metal pad is disposed on an upper surface thereof, a second circuit board disposed on the first circuit board, a solder ball disposed between the first circuit board and the second circuit board, and a first layer and a second layer sequentially disposed between the metal pad of the first circuit board and the solder ball in a direction from the metal pad to the solder ball, wherein the ball grid array package includes a section in which, from an interface between the first layer and the second layer to an interface between the second layer and the solder ball, a content of bismuth (Bi) increases and then decreases, and a content of copper (Cu) decreases and then increases.

A section including the highest point of the content of Bi in the second layer may coincide with a section including the lowest point of the content of Cu.

The metal pad may include Cu, the first layer may include tin (Sn) and Cu, the second layer may include Sn, silver (Ag), Cu, and Bi, and the solder ball may include Sn, Ag, and Cu.

A thickness of the first layer may be in a range of 0.1 μm to 2 μm.

The second layer may be disposed to extend from a lower surface of the solder ball toward the second circuit board along a side surface of the solder ball.

The second layer may be disposed to extend from a lower surface of the solder ball to a lower surface of the second circuit board along a side surface of the solder ball.

A ball grid array package according to yet another embodiment of the present invention includes a first circuit board in which a plurality of metal pads spaced apart from each other are disposed on an upper surface thereof, a second circuit board disposed on the first circuit board, a plurality of solder balls disposed to be spaced apart from each other between the first circuit board and the second circuit board, a plurality of first layers and a plurality of second layers sequentially disposed between the plurality of metal pads of the first circuit board and the plurality of solder balls in a direction from the plurality of metal pads to the plurality of solder balls, wherein the ball grid array package includes a section in which, from an interface between each first layer and each second layer to an interface between each second layer and each solder ball, a content of Bi increases and then decreases, and a content of Cu decreases and then increases.

Each of the second layers may extend from a lower surface of each of the solder balls toward the second circuit board along a side surface of each of the solder balls.

The plurality of second layers may be disposed on side surfaces of the plurality of solder balls to be spaced apart from each other.

Each of the second layers may be disposed to extend from a lower surface of each of the solder balls to a lower surface of the second circuit board along a side surface of each of the solder balls.

### Advantageous Effects

According to embodiments of the present invention, a ball grid array package having improved reliability against external shock can be obtained. In addition, according to embodiments of the present invention, the amount of material required to fill a space between solder balls can be reduced, and a manufacturing process of a ball grid array package can be simplified. In addition, according to embodiments of the present invention, the problem of cracks occurring in solder balls can be maximally reduced.

### DESCRIPTION OF DRAWINGS

FIG. 1 is a top view of a ball grid array package according to one embodiment of the present invention.

FIG. 2 is a cross-sectional view of the ball grid array package according to one embodiment of the present invention.

FIG. 3 is a flowchart illustrating a process of manufacturing a ball grid array package according to an embodiment of the present invention.

FIG. 4 shows cross-sectional views of ball grid array packages according to comparative examples and an example.

FIG. 5 shows cross-sectional images of the ball grid array packages according to the comparative examples and the example.

FIGS. 6 and 7 are cross-sectional views of a ball grid array package according to another embodiment of the present invention.

FIG. 8 is a flowchart illustrating a process of manufacturing a ball grid array package according to another embodiment of the present invention.

FIG. 9 is a cross-sectional view of the ball grid array package according to still another embodiment of the present invention.

FIG. 10 is a graph showing a composition change for each layer in the ball grid array package according to still another embodiment of the present invention.

FIG. 11 is a cross-sectional view of a ball grid array package according to yet another embodiment of the present invention.

FIG. 12 is a cross-sectional view of the ball grid array package according to yet another embodiment of the present invention.

FIG. 13 is a flowchart illustrating a process of manufacturing a ball grid array package according to an embodiment of the present invention.

FIG. 14A is a cross-sectional image of a ball grid array package manufactured according to comparative example 11, and FIG. 14B is a cross-sectional image of a ball grid array package manufactured according to example 11.

### MODES OF THE INVENTION

Hereinafter, exemplary embodiments of the present invention will be described with reference to the accompanying drawings.

However, the technical spirit of the present invention is not limited to the few embodiments which will be described and may be realized using various other embodiments, and at least one component of the embodiments may be selectively coupled, substituted, and used to realize the technical spirit within the range of the technical spirit of the present invention.

In addition, unless clearly and specifically defined otherwise by context, all terms (including technical and scientific terms) used herein may be interpreted as having customary meanings to those skilled in the art, and meanings of generally used terms, such as those defined in commonly used dictionaries, will be interpreted by considering contextual meanings of the related technology.

In addition, the terms used in the embodiments of the present invention are for the purpose of describing the embodiments and are not intended to limit the present invention.

In the present specification, unless clearly indicated otherwise by the context, singular forms include the plural forms thereof, and in a case in which “at least one (or one or more) among A, B, and C” is described, this may include at least one combination among all combinations which may be combined with A, B, and C.

In addition, in descriptions of components of the present invention, terms such as “first,” “second,” “A,” “B,” “(a),” and “(b)” may be used.

The terms are only to distinguish one element from another element, and an essence, order, and the like of the elements are not limited by the terms.

In addition, it should be understood that, when an element is referred to as being “connected” or “coupled” to another element, such a description may include both of a case in which the element is directly connected or coupled to the other element and a case in which the element is connected or coupled to the other element with still another element disposed therebetween.

In addition, in a case in which any one element is described as being formed or disposed “on or below” another element, such a description includes both cases in which the two elements are formed or disposed in direct contact with each other and in which one or more other elements are interposed between the two elements. In addition, when one element is described as being disposed “on or under” another element, such a description may include a case in which the one element is disposed at an upper side or a lower side with respect to the other element.

Hereinafter, embodiments will be described in detail with reference to the accompanying drawing, wherein like reference numerals refer to the same or corresponding components regardless of reference number, and a redundant description thereof will be omitted.

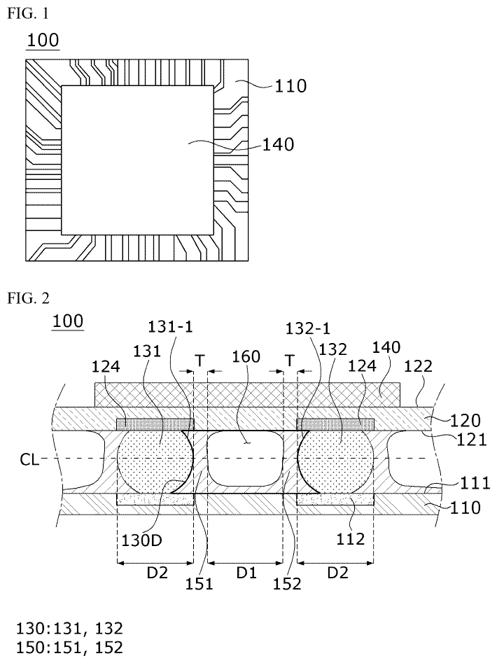

FIG. 1 is a top view of a ball grid array package according to one embodiment of the present invention. FIG. 2 is a cross-sectional view of the ball grid array package according to one embodiment of the present invention.

Referring to FIGS. 1 and 2, a ball grid array package 100 includes a first circuit board 110, a second circuit board 120 disposed on the first circuit board 110, and a plurality of solder balls 130 disposed to be spaced apart from each other between the first circuit board 110 and the second circuit board 120.

The first circuit board 110 may be a single-layer or multi-layer printed circuit board. The first circuit board 110 may include a pad 112 disposed on an upper surface of the first circuit board 110. The pad 112 may include a conductive material, for example, a metal, and a plurality of pads 112 may be disposed to be spaced a predetermined interval apart from each other and may be connected to a line pattern of the first circuit board 110. In FIG. 2, the first pad 112 is illustrated as being disposed to be engraved in the upper surface of the first circuit board 110, but the present invention is not limited thereto. The first pad 112 may be disposed to be embossed on the upper surface of the first circuit board 110.

The second circuit board 120 includes a first surface 121 and a second surface 122 which is a surface opposite to the first surface 121. The first surface 121 of the second circuit board 120 may be a surface facing the first circuit board 110, and an integrated circuit (IC) chip 140 may be disposed on the second surface 122 of the second circuit board 120.

In the present specification, for convenience of description, a surface of the first circuit board 110 facing the second circuit board 120 may be an upper surface 111 of the first circuit board 110, and a surface of the second circuit board 120 facing the first circuit board 110 may be a lower surface 121 of the second circuit board 120.

The second circuit board 120 may be a printed circuit board. The second circuit board 120 may be an interposer board. Accordingly, the second circuit board 120 may include an insulating body, metal line layers disposed on both surfaces of the insulating body, and vias that pass through the insulating body to electrically connect the metal line layers.

The second circuit board 120 may be electrically connected to the IC chip 140, may supply power to the IC chip 140, may input a signal to the IC chip 140, and may transmit a signal output from the IC chip 140 to the first circuit board 110.

The second circuit board 120 may include a pad 124 disposed on the lower surface of the second circuit board 120. The pad 124 may include a conductive material, for example, a metal, and a plurality of pads 124 may be disposed to be spaced a predetermined interval apart from each other and may be electrically connected to the IC chip 140 through an internal pad or a via (not shown) of the second circuit board 120. In FIG. 2, the second pad 124 is illustrated as being disposed to be engraved in the lower surface of the second circuit board 120, but the present invention is not limited thereto. The second pad 124 may be disposed to be embossed on the lower surface of the second circuit board 120.

The pad 112 of the first circuit board 110 and the pad 124 of the second circuit board 120 may be connected by the solder ball 130.

In the ball grid array package 100 according to the embodiment of the present invention, the plurality of solder balls 130 are disposed to be spaced apart from each other, and a bonding agent 150 is disposed along side surfaces of the plurality of solder balls 130 from the upper surface 111 of the first circuit board 110 to the lower surface 121 of the second circuit board 120 between the first circuit board 110 and the second circuit board 120. Accordingly, the bonding agent 150 may stably bond the upper surface 111 of the first circuit board 110 and the solder ball 130, and the lower surface 121 of the second circuit board 120 and the solder ball 130. In addition, the bonding agent 150 may reinforce a portion between the upper surface 111 of the first circuit board 110 and the solder ball 130, a portion between the lower surface 121 of the second circuit board 120 and the solder ball 130, and a side surface of the solder ball 130, thereby reducing the possibility of cracks occurring in the solder ball 130.

According to an embodiment of the present invention, a channel 160 surrounded by the bonding agent 150 is formed between the first circuit board 110 and the second circuit board 120, and an area of the channel 160 is in a range of 30% to 70% or preferably 50% to 70% of an area of a separation area 130D between the plurality of solder balls 130. Here, the channel 160 may be an empty space surrounded by the bonding agent 150 between the first circuit board 110 and the second circuit board 120. In this way, when the channel 160 surrounded by the bonding agent 150 is formed between the first circuit board 110 and the second circuit board 120, gas generated by the first circuit board 110, the second circuit board 120, and the bonding agent 150 during a reflow process can be discharged to the outside through the channel 160. Accordingly, fine and non-uniform voids formed in the bonding agent 150 can be minimized. In this case, when the area of the channel 160 is less than 30% of that of the separation area 130D between the plurality of solder balls 130, outgassing through the channel 160 does not occur sufficiently, which may cause fine and non-uniform voids in the bonding agent 150, and when the area of the channel 160 exceeds 70% of that of the separation area 130D between the plurality of solder balls 130, the reinforcing effect of the bonding agent 150 is reduced, which may cause cracks in the solder balls 130.

Hereinafter, the ball grid array package 100 according to the embodiment of the present invention will be described in more detail with reference to the cross-sectional view of FIG. 2. According to an embodiment of the present invention, a first solder ball 131 and a second solder ball 132 are disposed to be spaced apart from each other between the first circuit board 110 and the second circuit board 120, a first bonding agent 151 is disposed along a first side surface 131-1 of the first solder ball 131 from the upper surface 111 of the first circuit board 110 to the lower surface 121 of the second circuit board 120 between the first circuit board 110 and the second circuit board 120, and a second bonding agent 152 is disposed along a second side surface 132-1 of the second solder ball 132 from the upper surface 111 of the first circuit board 110 to the lower surface 121 of the second circuit board 120 between the first circuit board 110 and the second circuit board 120. Accordingly, the first bonding agent 151 stably bonds the upper surface 111 of the first circuit board 110 and the first solder ball 131, and the lower surface 121 of the second circuit board 120 and the first solder ball 131, and reinforces the first side surface 131-1 of the first solder ball 131, and the second bonding agent 152 stably bonds the upper surface 111 of the first circuit board 110 and the second solder ball 132, and the lower surface 121 of the second circuit board 120 and the second solder ball 132, and reinforces the second side surface 132-1 of the second solder ball 132, thereby reducing the possibility of cracks occurring in the first solder ball 131 and the second solder ball 132.

Here, the first side surface 131-1 of the first solder ball 131 and the second side surface 132-1 of the second solder ball 132 face each other, and the first bonding agent 151 and the second bonding agent 152 form the channel 160, wherein the first bonding agent 151 is disposed along the first side surface 131-1 of the first solder ball 131 from the upper surface 111 of the first circuit board 110 to the lower surface 121 of the second circuit board 120 between the first circuit board 110 and the second circuit board 120, and the second bonding agent 152 is deposed along the second side surface 132-1 of the second solder ball 132 from the upper surface 111 of the first circuit board 110 to the lower surface 121 of the second circuit board 120 between the first circuit board 110 and the second circuit board 120. In this case, the area of the channel 160 between the first bonding agent 151 and the second bonding agent 152 is in a range of 30% to 70% or preferably 50% to 70% of the area of the separation area 130D between a side surface of the first solder ball 131 and a side surface of the second solder ball 132. Here, the area of the channel 160 and the area of the separation area 130D are a cross-sectional area between the first circuit board 110 and the second circuit board 120 on a cross section of FIG. 2. In this way, when the first bonding agent 151 and the second bonding agent 152 form the channel 160 between the first side surface 131-1 of the first solder ball 131 and the second side surface 132-1 of the second solder ball 132, gas generated by the first circuit board 110, the second circuit board 120, the first bonding agent 151, and the second bonding agent 152 during a reflow process can be discharged to the outside through the channel 160 between the first bonding agent 151 and the second bonding agent 152. Accordingly, fine and non-uniform voids formed in the first bonding agent 151 and the second bonding agent 152 can be minimized. In this case, when a ratio between the area of the channel 160 between the first bonding agent 151 and the second bonding agent 152 and the area of the separation area 130D between the first side surface 131-1 of the first solder ball 131 and the second side surface 132-1 of the second solder ball 132 satisfies such a numerical range, both the outgassing effect and the reinforcing effect of the bonding agent 150 can be obtained.

According to an embodiment of the present invention, the maximum separation distance D1 between the first bonding agent 151 and the second bonding agent 152 forming the channel 160 may be 50% or more, preferably in a range of 50% to 300%, or more preferably in a range of 50% to 200% of a diameter D2 of at least one of the first solder ball 131 and the second solder ball 132. Here, the maximum separation distance D1 between the first bonding agent 151 and the second bonding agent 152 may be a distance in a direction parallel to the first circuit board 110 or the second circuit board 120. The maximum separation distance D1 between the first bonding agent 151 and the second bonding agent 152 may be the maximum width of the channel 160 in a direction parallel to the first circuit board 110 or the second circuit board 120. Accordingly, since gas generated during a reflow process can be released to the outside through the channel 160 between the first bonding agent 151 and the second bonding agent 152, fine and non-uniform voids formed in the first bonding agent 151 and the second bonding agent 152 can be minimized, and since the first solder ball 131 and the second solder ball 132 are reinforced by the first bonding agent 151 and the second bonding agent 152, the problem of cracks occurring in the first solder ball 131 and the second solder ball 132 can be prevented.

According to an embodiment of the present invention, at least one of a horizontal thickness T of the first bonding agent 151 on the first side surface 131-1 of the first solder ball 131 and a horizontal thickness T of the second bonding agent 152 on the second side surface 132-1 of the second solder ball 132 on a center line CL between the first circuit board 110 and the second circuit board 120 may be in a range of 10% to 50% or less, preferably 10% to 40%, or more preferably 10% to 30% of at least one of the diameter D2 of the first solder ball 131 and the diameter D2 of the second solder ball 132. When at least one of the horizontal thickness T of the first bonding agent 151 on the first side surface 131-1 of the first solder ball 131 and the horizontal thickness T of the second bonding agent 152 on the second side surface 132-1 of the second solder ball 132 is less than such a numerical range, since the reinforcing effect of the bonding agent is reduced, cracks may occur in the first solder ball 131 and the second solder ball 132. When at least one of the horizontal thickness T of the first bonding agent 151 on the first side surface 131-1 of the first solder ball 131 and the horizontal thickness T of the second bonding agent 152 on the second side surface 132-1 of the second solder ball 132 exceeds such a numerical range, since outgassing does not occur sufficiently, fine and non-uniform voids may be formed in the first bonding agent 151 and the second bonding agent 152. Here, a horizontal direction may be a direction parallel to the first circuit board 110 or a direction parallel to the second circuit board 120.

According to an embodiment of the present invention, at least one of the horizontal thickness T of the first bonding agent 151 on the first side surface 131-1 of the first solder ball 131 and the horizontal thickness T of the second bonding agent 152 on the second side surface 132-1 of the second solder ball 132 on the center line CL between the first circuit board 110 and the second circuit board 120 may be in a range of 5 μm to 20 μm. When at least one of the horizontal thickness T of the first bonding agent 151 on the first side surface 131-1 of the first solder ball 131 and the horizontal thickness T of the second bonding agent 152 on the second side surface 132-1 of the second solder ball 132 is less than such a numerical range, since the reinforcing effect of the bonding agent is reduced, cracks may occur in the first solder ball 131 and the second solder ball 132. When at least one of the horizontal thickness T of the first bonding agent 151 on the first side surface 131-1 of the first solder ball 131 and the horizontal thickness T of the second bonding agent 152 on the second side surface 132-1 of the second solder ball 132 exceeds such a numerical range, since outgassing does not occur sufficiently, fine and non-uniform voids may be formed in the first bonding agent 151 and the second bonding agent 152.

According to an embodiment of the present invention, the first bonding agent 151 and the second bonding agent 152 may meet each other on at least one of the upper surface 111 of the first circuit board 110 and the lower surface 121 of the second circuit board 120. Accordingly, the first bonding agent 151 and the second bonding agent 152 can reinforce the upper surface 111 of the first circuit board 110 and the lower surface 121 of the second circuit board 120 to prevent damage to the ball grid array package 100 due to external shock.

According to an embodiment of the present invention, an area of the first bonding agent 151 and the second bonding agent 152 in contact with the upper surface 111 of the first circuit board 110 may be greater than an area of the first bonding agent 151 and the second bonding agent 152 in contact with the lower surface 121 of the second circuit board 120. Alternatively, in an area vertically overlapping the channel 160, a vertical thickness of the first bonding agent 151 and the second bonding agent 152 disposed on the upper surface 111 of the first circuit board 110 may be greater than a vertical thickness of the first bonding agent 151 and the second bonding agent 152 disposed on the lower surface 121 of the second circuit board 120. For example, as shown in FIG. 2, the first bonding agent 151 and the second bonding agent 152 may be disposed to meet each other on the upper surface 111 of the first circuit board 110, in the area vertically overlapping the channel 160, but the first bonding agent 151 and the second bonding agent 152 may be disposed to not meet each other on the lower surface 121 of the second circuit board 120. That is, the first bonding agent 151 and the second bonding agent 152 may be disposed on the entire upper surface 111 of the first circuit board 110 in the area vertically overlapping the channel 160, but the first bonding agent 151 and the second bonding agent 152 may be disposed on only a portion of the lower surface 121 of the second circuit board 120. In this case, there may be an area in which a thickness of the first bonding agent 151 and the second bonding agent 152 on the upper surface 111 of the first circuit board 110 in the area vertically overlapping the channel 160 gradually decreases in a horizontal direction toward a center of the channel 160. There may be an area in which a thickness of the first bonding agent 151 and the second bonding agent 152 on the lower surface 121 of the second circuit board 120 in the area vertically overlapping the channel 160 gradually decreases in the horizontal direction toward the center of the channel 160, and there may also be an area in which a thickness of the first bonding agent 151 and the second bonding agent 152 is 0 because the first bonding agent 151 and the second bonding agent 152 are not disposed. In an area that does not vertically overlap the channel 160, the first bonding agent 151 and the second bonding agent 152 may each fill a space from the upper surface 111 of the first circuit board 110 to the lower surface 121 of the second circuit board 120. That is, the thickness of the first bonding agent 151 and the thickness of the second bonding agent 152 in the area that does not vertically overlap the channel 160 may each be equal to a vertical distance from the upper surface 111 of the first circuit board 110 to the lower surface 121 of the second circuit board 120. Here, a vertical direction may be a direction from the first circuit board 110 to the second circuit board 120. Accordingly, a lower surface of the solder ball 130, which is more vulnerable to thermal shock than an upper surface of the solder ball 130, can be reinforced more efficiently.

According to an embodiment of the present invention, at least one of the first bonding agent 151 and the second bonding agent 152 may include an area of which a horizontal thickness in a direction parallel to the first circuit board 110 or the second circuit board 120 decreases and then increases again in a vertical direction from the first circuit board 110 to the second circuit board 120. That is, a thickness of at least one of the first bonding agent 151 and the second bonding agent 152 in a direction parallel to the first circuit board 110 or the second circuit board 120 may gradually decrease from the upper surface 111 of the first circuit board 110 to the center line CL between the first circuit board 110 and the second circuit board 120 and then may gradually increase from the center line CL between the first circuit board 110 and the second circuit board 120 to the lower surface 121 of the second circuit board 120. Accordingly, the bonding strength between the upper surface 111 of the first circuit board 110 and a lower portion of the solder ball 130 can be increased, and cracks in the lower portion of the solder ball 130, which may be more vulnerable to thermal shock to a center of the solder ball 130, can be prevented. Likewise, the bonding strength between the lower surface 121 of the second circuit board 120 and the upper surface of the solder ball 130 can be increased, and cracks in the upper surface of the solder ball 130, which may be more vulnerable to thermal shock than the center of the solder ball 130, can be prevented.

According to an embodiment of the present invention, the first bonding agent 151 and the second bonding agent 152 may include an epoxy resin, a curing agent, and an inorganic filler.

Here, the epoxy resin may have chemical resistance, reactivity, toughness, adhesion, and heat resistance. The epoxy resin may include at least one of a bisphenol A-type epoxy resin, a bisphenol F-type epoxy resin, and a naphthalene-type epoxy resin. For example, the bisphenol A-type epoxy resin may include bisphenol A diglycidyl ether, the bisphenol F-type epoxy resin may include at least one of a bisphenol F epichlorohydrin resin and bisphenol F diglycidyl ether, and the naphthalene-type epoxy resin may include 1,6-naphthalene diglycidyl ether. When the epoxy resin includes the naphthalene-type epoxy resin, the strength of the bonding agent 150 can be increased.

The curing agent may be a curing agent having a flux function. The curing agent having a flux function may be a curing agent that removes an oxide film on a surface of the solder ball 130 and then reacts with an oxirane group of an epoxy resin. Accordingly, in the present specification, the bonding agent 150 may be referred to as epoxy flux. The curing agent having a flux function according to the embodiment of the present invention is activated at a temperature of 130° C. or more to serve to remove an oxide film on the surface of a solder ball 130 at a temperature of 130° C. to 200° C. and prevent carbonization at a temperature of 250° C. or more. Accordingly, the curing agent having a flux function may react with an epoxy resin at high temperatures to delay curing and may have a function of preventing carbonization at high temperature.

For example, the curing agent having a flux function may include an anhydride and an acid. For example, the curing agent having a flux function may include an anhydride and an abietic acid. For example, the curing agent having a flux function may include hexahydromethylphthalic anhydride and rosin. The curing agent having a flux function may further include a pentanedioic acid. Accordingly, the curing agent having a flux function may remove an oxide film on the surface of the solder ball 130 to reduce the surface tension of the surface of the solder ball. The curing agent, which has completed a function of removing the oxide film on the surface of the solder ball 130, may react with an epoxy resin to remove acid activity. Accordingly, since there is no need to separately clean a flux, a manufacturing process of the ball grid array package 100 can be simplified, and the formation of fine and non-uniform voids in the bonding agent 150 can be minimized. In addition, since the curing of the epoxy resin is delayed due to a reaction between an acid of the curing agent having a flux function and the epoxy resin, outgassing efficiency can be increased.

The inorganic filler may include at least one of silica and carbon black. Accordingly, a thermal expansion coefficient and modulus of the bonding agent 150 can be improved. However, the inorganic filler may be included in an amount that does not interfere with bonding with the solder ball 130.

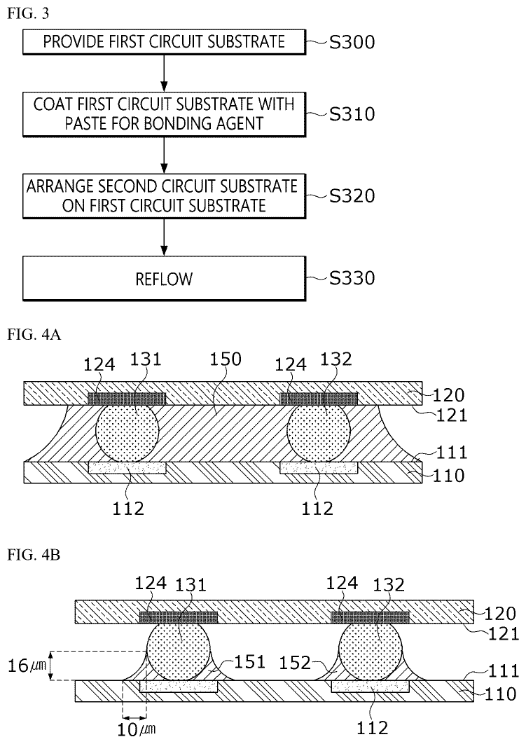

FIG. 3 is a flowchart illustrating a process of manufacturing a ball grid array package according to an embodiment of the present invention.

Referring to FIG. 3, a first circuit board 110 is provided (S300). As described above, the first circuit board 110 may be a single-layer or multi-layer printed circuit board including a pad 112 disposed on an upper surface 111.

Next, the first circuit board 110 is coated with a paste for a bonding agent (S310). The paste for a bonding agent may include an epoxy resin, a curing agent, and an inorganic filler, and the curing agent may be a curing agent having a flux function. For example, the epoxy resin may include a bisphenol A-type epoxy resin, a bisphenol F-type epoxy resin, and a naphthalene-type epoxy resin, the curing agent may include hexahydromethylphthalic anhydride and rosin, and the inorganic filler may include silica and carbon black. The first circuit board 110 may be coated with the paste for a bonding agent using at least one of dispensing, printing, and dipping processes.

Next, a second circuit board 120 in which a solder ball 130 array is disposed on a lower surface 121 is disposed on the first circuit board 110 (S320). In this case, the solder ball 130 array may be disposed to be arranged on the pad 112 of the first circuit board 110. An IC chip 140 may be disposed in advance on an upper surface 122 of the second circuit board 120.

Next, a reflow process is performed (S330). Accordingly, the paste for a bonding agent may be moved to the lower surface 121 of the second circuit board 120 along a side surface of the solder ball 130, the pad 112 of the first circuit board 110 and the solder ball 130 are bonded to each other, and a portion between the upper surface of the first circuit board 110 and the solder ball 130, the side surface of the solder ball 130, and a portion between the lower surface of the second circuit board 120 and the solder ball 130 may be reinforced. According to an embodiment of the present invention, when a paste for a bonding agent which includes a curing agent having a flux function is used, after the curing agent having a flux function removes an oxide film on a surface of the solder ball 130 during the reflow process, the epoxy resin may be cured to extend to the lower surface 121 of the second circuit board 120 along the side surface of the solder ball 130. Accordingly, there is no need for a separate flux cleaning process after reflow is performed, and reflow and solder ball reinforcement processes may be performed simultaneously.

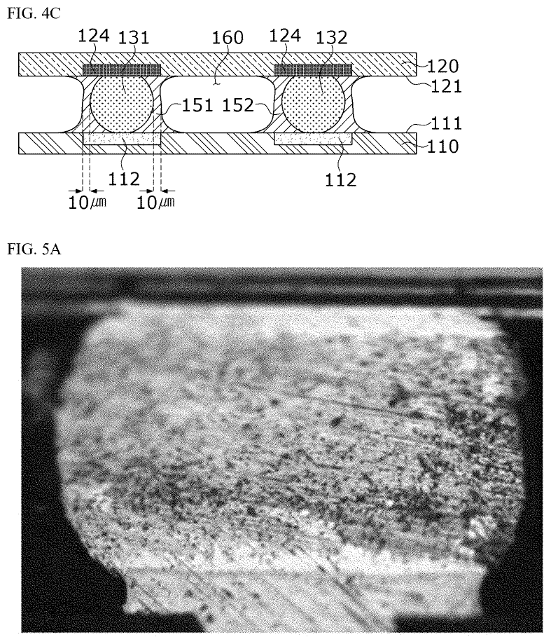

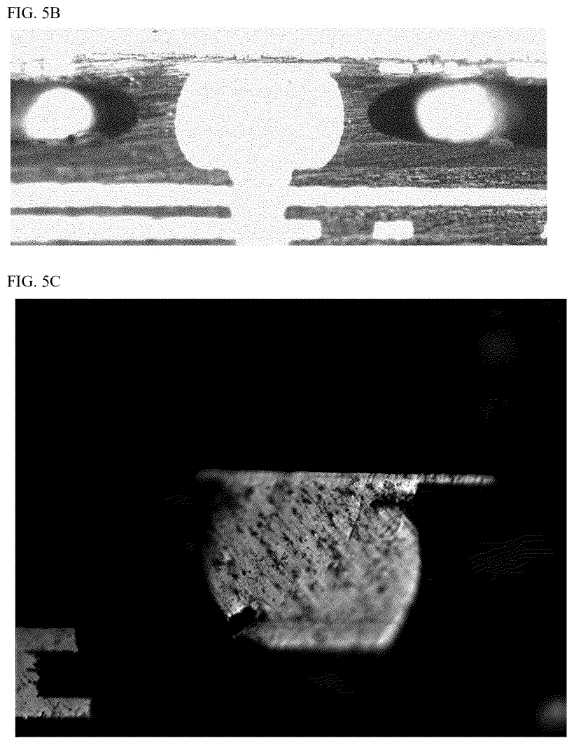

FIG. 4 shows cross-sectional views of ball grid array packages according to comparative examples and an example. Table 1 shows reliability test results during thermal shock according to the comparative examples and the example. FIG. 5 shows cross-sectional images of the ball grid array packages according to the comparative examples and the example.

According to comparative example 1 of FIG. 4A, in a structure including a first circuit board 110, a second circuit board 120 disposed on the first circuit board 110, and a first solder ball 131 and a second solder ball 132 disposed to be spaced apart from each other between the first circuit board 110 and the second circuit board 120, the entire space between the first solder ball 131 and the second solder ball 132 was filled with an epoxy flux.

According to comparative example 2 of FIG. 4B, in a structure including a first circuit board 110, a second circuit board 120 disposed on the first circuit board 110, and a first solder ball 131 and a second solder ball 132 disposed to be spaced apart from each other between the first circuit board 110 and the second circuit board 120, an epoxy flux was disposed only below the first solder ball 131 and the second solder ball 132. Here, lower portions of the first solder ball 131 and the second solder ball 132 may be areas closer to the first circuit board 110 with respect to an area corresponding to the maximum width of the first solder ball 131 and the second solder ball 132, and upper portions of the first solder ball 131 and the second solder ball 132 may be areas closer to the second circuit board 120 with respect to the area which corresponds to the maximum width of the first solder ball 131 and the second solder ball 132. Here, a width of the first solder ball 131 and the second solder ball 132 may be a width in a horizontal direction parallel to the first circuit board 110 and the second circuit board 120, and the maximum width of the first solder ball 131 and the second solder ball 132 may be the maximum width of the first solder ball 131 and the second solder ball 132 in a horizontal direction. That is, as shown, the epoxy flux filled a space from an upper surface of the pad 112 to a height of 16 μm along side surfaces of the first solder ball 131 and the second solder ball 132 and was not disposed on the upper portions of the first solder ball 131 and the second solder ball 132. On the upper surface of the pad 112, the epoxy flux was horizontally disposed to a distance of 10 μm from a point on the upper surface of the pad 112 corresponding to the maximum width of the first solder ball 131 and the second solder ball 132.

According to the example of FIG. 4C, in a structure including a first circuit board 110, a second circuit board 120 disposed on the first circuit board 110, and a first solder ball 131 and a second solder ball 132 disposed to be spaced apart from each other between the first circuit board 110 and the second circuit board 120, an epoxy flux was disposed along a side surface of the first solder ball 131 from an upper surface 111 of the first circuit board 110 to a lower surface 121 of the second circuit board 120 and was disposed along a side surface of the second solder ball 132 from the upper surface 111 of the first circuit board 110 to the lower surface 121 of the second circuit board 120. In this case, the side surface of the first solder ball 131 and the side surface of the second solder ball 132 were disposed to face each other, and the epoxy flux formed a channel area between the side surface of the first solder ball 131 and the side surface of the second solder ball 132. In this case, the epoxy flux was horizontally disposed to a distance of 10 μm from the side surfaces which correspond to the maximum width of the first solder ball 131 and the second solder ball 132.

TABLE 1

| | | First test | | | Second test | | |
|---|---|---|---|---|---|---|---|
| Experiment | Reference | Comparative | Comparative | | Comparative | Comparative | |
| number | example | example 1 | example 2 | Example | example 1 | example 2 | Example |
| Fatigue life | 1,850 | 1,580 | 1,692 | 2,053 | 1,586 | 1,709 | 2,053 |
| [cycle] | | | | | | | |
| Relative life | 1.000 | 0.854 | 0.915 | 1.110 | 0.857 | 0.924 | 1.110 |
| [cycle] | | | | | | | |

In Table 1, in a structure of a reference example including a first circuit board 110, a second circuit board 120 disposed on the first circuit board 110, and a first solder ball 131 and a second solder ball 132 disposed to be spaced apart from each other between the first circuit board 110 and the second circuit board 120, an epoxy flux was not disposed.

In a thermal shock test performed under conditions in which a temperature changes from −40° C. to 80° C. and a dwell time is 10 minutes, in the structure according to the example, it can be seen that significantly high reliability results are obtained as compared to the structures according to the reference example, comparative example 1, and comparative example 2.

FIG. 5A is a cross-sectional image of the ball grid array according to the example, FIG. 5B is a cross-sectional image of the solder ball of the ball grid array according to the example, and FIG. 5C is a cross-sectional image of a ball grid array according to the reference example after a thermal shock test. Referring to FIG. 5C, it can be seen that cracks occur in the solder ball after the thermal shock test.

According to an embodiment of the present invention, an amount of used epoxy flux may be reduced as compared to comparative example 1 in which the epoxy flux fills the entire space between the solder balls. In addition, according to an embodiment of the present invention, since a reflow process is performed after an epoxy flux is applied, bonding between the pad 112 of the first circuit board 110 and the solder balls 131 and 132 and the reinforcement of the side surfaces of the solder balls 131 and 132 may be performed simultaneously. Accordingly, a manufacturing process and a manufacturing time can be significantly reduced as compared to comparative example 1 in which the epoxy flux fills the entire space between the solder balls after the reflow process.

In addition, when the entire space between the first solder ball 131 and the second solder ball 132 is filled with an epoxy flux as in comparative example 1, since outgassing from the epoxy flux, the first circuit board 110, and the second circuit board 120 cannot efficiently performed, fine and non-uniform voids are formed inside a bonding agent, which may result in lowering reliability due to thermal shock.

On the other hand, according to comparative example 2 and the example, outgassing from the epoxy flux, the first circuit board 110, and the second circuit board 120 can be performed efficiently so that high reliability can be obtained as compared to comparative example 1.

However, in comparative example 2 in which the epoxy flux is disposed only below the first solder ball 131 and the second solder ball 132, since the upper portions of the first solder ball 131 and the second solder ball 132 cannot be reinforced, cracks may occur in the upper portions of the first solder ball 131 and the second solder ball 132, resulting in lower reliability as compared to the example.

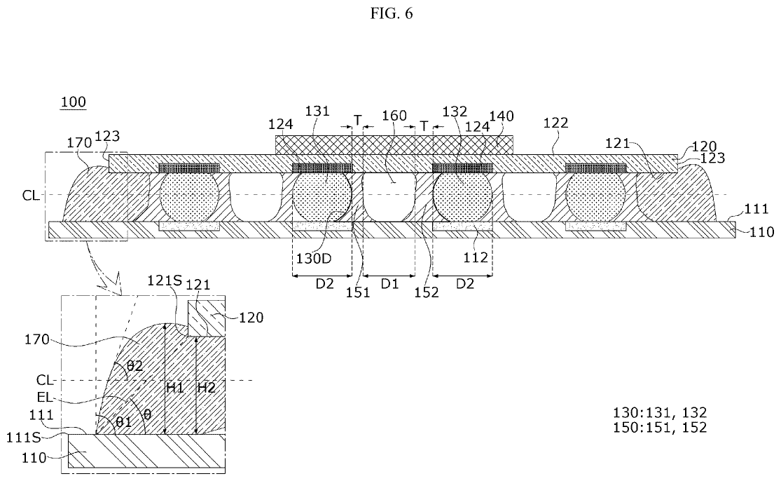

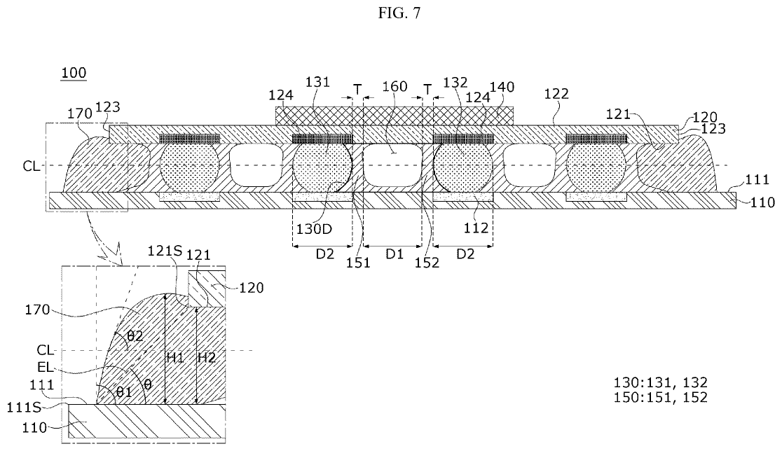

FIGS. 6 and 7 are cross-sectional views of a ball grid array package according to another embodiment of the present invention. Redundant descriptions of the same contents as those described with reference to FIGS. 1 to 5 are omitted.

Referring to FIGS. 6 and 7, a ball grid array package 100 includes a first circuit board 110, a second circuit board 120 disposed on the first circuit board 110, and a plurality of solder balls 130 disposed to be spaced apart from each other between the first circuit board 110 and the second circuit board 120.

The ball grid array package 100 according to another embodiment of the present invention further includes a filling member 170 disposed along an edge of the second circuit board 120 on the first circuit board 110. Since the filling member 170 according to the embodiment of the present invention fills a space between an upper surface 111 of the first circuit board 110 and a lower surface 121 of the second circuit board 120 along the edge of the second circuit board 120, the filling member 170 may be referred to as a side fill.

The filling member 170 according to the embodiment of the present invention may be an epoxy resin composition including an epoxy resin, a curing agent, and an inorganic filler.

Here, the epoxy resin may have chemical resistance, reactivity, toughness, adhesion, and heat resistance. The epoxy resin may include at least one of a bisphenol A-type epoxy resin, a bisphenol F-type epoxy resin, and a naphthalene-type epoxy resin.

The curing agent may include at least one of an amine-based curing agent, a phenol-based curing agent, an acid anhydride-based curing agent, a polymercaptan-based curing agent, a polyaminoamide-based curing agent, an isocyanate-based curing agent, and a blocked isocyanate-based curing agent, and two or more types of curing agents may be mixed and used. According to an embodiment of the present invention, the curing agent may be a curing agent having a flux function. The curing agent having a flux function may be a curing agent that removes an oxide film on a surface of the solder ball 130 and then reacts with an epoxy resin.

The inorganic filler may include at least one of aluminum oxide, boron nitride, aluminum nitride, silica, carbon black, silicon carbide, and graphite.

However, a composition of the filling member 170 is not limited thereto, and the filling member 170 according to the embodiment of the present invention may include a known underfill material applied to a ball grid array package.

According to an embodiment of the present invention, a surface of the filling member 170 has a shape that is convex outward from a virtual extension line EL from an edge of the filling member 170 disposed on the upper surface 111 of the first circuit board 110 to an edge of the lower surface 121 of the second circuit board 120. Here, the edge of the filling member 170 disposed on the upper surface 111 of the first circuit board 110 may be an edge of the filling member 170 disposed close to an outer edge 111S of the upper surface 111 of the first circuit board 110. The edge of the lower surface 121 of the second circuit board 120 may be an outer edge 121S of the lower surface 121 of the second circuit board 120. The virtual extension line EL from the edge of the filling member 170 disposed on the upper surface 111 of the first circuit board 110 to the edge of the lower surface 121 of the second circuit board 120 may be a line virtually connected from the edge of the filling member 170 disposed on the upper surface 111 of the first circuit board 110 to the edge of the lower surface 121 of the second circuit board 120. The fact that the surface of the filling member 170 has a convex shape with respect to the virtual extension line EL may mean that the surface of the filling member 170 is positioned at a higher level than the virtual extension line EL. That is, it may mean that the filling member 170 is disposed on the virtual extension line EL.

Accordingly, since a sufficient amount of filling member 170 is disposed between the first circuit board 110 and the second circuit board 120, a portion between the first circuit board 110 and the second circuit board 120 may be stably supported, and a space between the first circuit board 110 and the second circuit board 120 may be protected from external foreign materials, thermal shock, or vibrations.

According to an embodiment of the present invention, the virtual extension line EL from the edge of the filling member 170 disposed on the upper surface 111 of the first circuit board 110 to the edge of the lower surface 121 of the second circuit board 120 may have an angle θ of 45° to 90° with respect to the upper surface 111 of the first circuit board 110. When an angle between the virtual extension line EL and the upper surface 111 of the first circuit board 110 is less than 45°, the filling member 170 is spread widely on the upper surface 111 of the first circuit board 110 to be close to the edge 111S of the upper surface 111 of the first circuit board 110, which may mean that the filling member 170 is wasted more than necessary, and when the angle between the virtual extension line EL and the upper surface 111 of the first circuit board 110 exceeds 90°, the filling member 170 is positioned inside the edge 121S of the lower surface 121 of the second circuit board 120 on the upper surface 111 of the first circuit board 110, which may mean that a sufficient amount of filling member 170 is not disposed to stably support the portion between the first circuit board 110 and the second circuit board 120.

According to an embodiment of the present invention, a section may be included in which an angle between the surface of the filling member 170 and the upper surface 111 of the first circuit board 110 decreases in a direction from the first circuit board 110 to the second circuit board 120. For example, the angle θ1 between the edge of the filling member 170 disposed on the upper surface 111 of the first circuit board 110 and the upper surface 111 of the first circuit board 110 may be greater than an angle θ2 between the surface of the filling member 170 and the upper surface 111 of the first circuit board 110 on a virtual center line CL between the first circuit board 110 and the second circuit board 120. Accordingly, since a sufficient amount of filling member 170 is disposed between the first circuit board 110 and the second circuit board 120, the portion between the first circuit board 110 and the second circuit board 120 may be stably supported, and the space between the first circuit board 110 and the second circuit board 120 may be protected from external foreign materials, thermal shock, or vibrations.

According to an embodiment of the present invention, at least a portion of the filling member 170 may be disposed on a side surface of the second circuit board 120. For example, at least a portion of the filling member 170 may be disposed on the edge of the lower surface 121 of the second circuit board 120 and may be further disposed on a side surface 123 of the second circuit board 120. Accordingly, the filling member 170 may support not only the lower surface 121 of the second circuit board 120 but also the side surface 123, may seal a space between the upper surface 111 of the first circuit board 110 and the lower surface 121 of the second circuit board 120, and may protect the space between the first circuit board 110 and the second circuit board 120 from external foreign materials, thermal shock, or vibrations.

According to an embodiment of the present invention, with respect to the upper surface 111 of the first circuit board 110, a maximum height H1 of the filling member 170 may be greater than a height H2 of the lower surface 121 of the second circuit board 120. Accordingly, the filling member 170 may support not only the lower surface 121 of the second circuit board 120 but also the side surface 123, may seal the space between the upper surface 111 of the first circuit board 110 and the lower surface 121 of the second circuit board 120, and may protect the space between the first circuit board 110 and the second circuit board 120 from external foreign materials, thermal shock, or vibrations.

In the ball grid array package 100 according to another embodiment of the present invention, as shown in FIG. 6, a plurality of solder balls 130 are disposed to be spaced apart from each other, and a bonding agent 150 is disposed along side surfaces of the plurality of solder balls 130 from the upper surface 111 of the first circuit board 110 between the first circuit board 110 and the second circuit board 120. Accordingly, the bonding agent 150 may stably bond the upper surface 111 of the first circuit board 110 and the solder ball 130, and the bonding agent 150 may reinforce a portion between the upper surface 111 of the first circuit board 110 and the solder ball 130 and the side surface of the solder ball 130, thereby reducing the possibility of cracks occurring in the solder ball 130.

As shown in FIG. 7, the plurality of solder balls 130 are disposed to be spaced apart from each other, and the bonding agent 150 is disposed along the side surfaces of the plurality of solder balls 130 from the upper surface 111 of the first circuit board 110 to the lower surface 121 of the second circuit board 120 between the first circuit board 110 and the second circuit board 120. Accordingly, the bonding agent 150 can stably bond the upper surface 111 of the first circuit board 110 and the solder ball 130, and the lower surface 121 of the second circuit board 120 and the solder ball 130, and the bonding agent 150 can reinforce the portion between the upper surface 111 of the first circuit board 110 and the solder ball 130, a portion between the lower surface 121 of the second circuit board 120 and the solder ball 130, and the side surface of the solder ball 130, thereby reducing the possibility of cracks occurring in the solder ball 130.

For the bonding agent 150 and a channel 160 surrounded by at least some of the upper surface 111 of the first circuit board 110, the bonding agent 150, the side surface of the solder ball 130, and the lower surface 121 of the second circuit board 120 between the first circuit board 110 and the second circuit board 120, redundant descriptions of the same contents as those described with reference to FIGS. 1 to 5 are omitted.

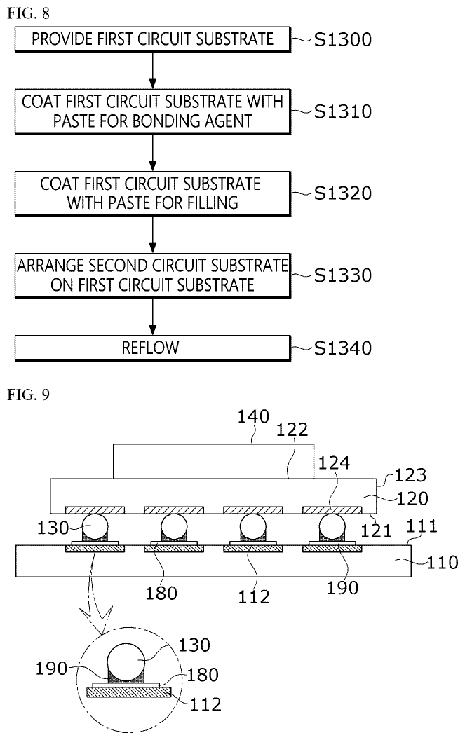

FIG. 8 is a flowchart illustrating a process of manufacturing a ball grid array package according to another embodiment of the present invention.

Referring to FIG. 8, a first circuit board 110 is provided (S1300). As described above, the first circuit board 110 may be a single-layer or multi-layer printed circuit board including a pad 112 disposed on an upper surface 111.

Next, the first circuit board 110 is coated with a paste for a bonding agent (S1310). The paste for a bonding agent may include an epoxy resin, a curing agent, and an inorganic filler, and the curing agent may be a curing agent having a flux function. For example, the epoxy resin may include a bisphenol A-type epoxy resin, a bisphenol F-type epoxy resin, and a naphthalene-type epoxy resin, the curing agent may include hexahydromethylphthalic anhydride and rosin, and the inorganic filler may include silica and carbon black. The first circuit board 110 may be coated with the paste for a bonding agent using at least one of dispensing, printing, and dipping processes. The pad 112 of the first circuit board 110 may be coated with the paste for a bonding agent.

Next, the first circuit board 110 is coated with a paste for filling (S1320). The filling paste may include an epoxy resin, a curing agent, and an inorganic filler. For example, the epoxy resin may include at least one of a bisphenol A-type epoxy resin, a bisphenol F-type epoxy resin, and a naphthalene-type epoxy resin, the curing agent may include at least one of an amine-based curing agent, a phenol-based curing agent, an acid anhydride-based curing agent, a polymercaptan-based curing agent, a polyaminoamide-based curing agent, an isocyanate-based curing agent, and a blocked isocyanate-based curing agent, and the inorganic filler may include at least one of aluminum oxide, boron nitride, aluminum nitride, silica, carbon black, silicon carbide, and graphite. The filling paste may be applied to not overlap the pad 112 of the first circuit board 110. For example, the filler paste may be applied to be spaced apart from the paste for a bonding agent and surround the paste for a bonding agent. The filling paste may be applied in consideration of a size of a second circuit board 120. For example, the filling paste may be applied such that an edge of a lower surface of the second circuit board 120 is disposed on the filling paste. The filling paste and the paste for a bonding agent may have the same composition. When the filling paste and the paste for a bonding agent have the same composition, the formation of a bonding agent 150 and the formation of a filling member 170 may be performed simultaneously under the same conditions, and thus a reflow process may be simplified.

Next, the second circuit board 120 in which a solder ball 130 array is disposed on a lower surface 121 is disposed on the first circuit board 110 (S1330). In this case, the solder ball 130 array may be disposed to be arranged on the pad 112 of the first circuit board 110, and an edge of the lower surface 121 of the second circuit board 120 may be disposed on an upper surface of the filling member 170. An IC chip 140 may be disposed in advance on an upper surface 122 of the second circuit board 120.

Next, a reflow process is performed (S1340). Accordingly, the paste for a bonding agent may be moved to the lower surface 121 of the second circuit board 120 along a side surface of a solder ball 130, the pad 112 of the first circuit board 110 and the solder ball 130 are bonded to each other, and a portion between an upper surface of the first circuit board 110 and the solder ball 130, the side surface of the solder ball 130, and a portion between the lower surface of the second circuit board 120 and the solder ball 130 may be reinforced. According to an embodiment of the present invention, when a paste for a bonding agent which includes a curing agent having a flux function is used, after the curing agent having a flux function removes an oxide film on a surface of the solder ball 130 during the reflow process, the epoxy resin may be cured to extend to the lower surface 121 of the second circuit board 120 along the side surface of the solder ball 130. In addition, since the second circuit board 120 is pressed during the reflow process, the filling paste may be cured into a convex shape along the edge of the lower surface 121 of the second circuit board 120. Accordingly, there is no need for a separate flux cleaning process after reflow is performed, and reflow and solder ball reinforcement processes may be performed simultaneously.

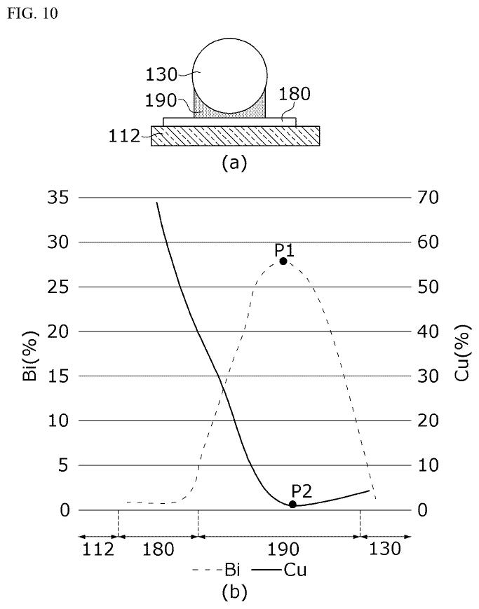

FIG. 9 is a cross-sectional view of a ball grid array package according to still another embodiment of the present invention FIG. 10 is a graph showing a composition change for each layer in the ball grid array package according to still another embodiment of the present invention. Redundant descriptions of the same contents as those described with reference to FIGS. 1 to 8 are omitted.

Referring to FIG. 9, a ball grid array package 100 includes a first circuit board 110, a second circuit board 120 disposed on the first circuit board 110, and a plurality of solder balls 130 disposed to be spaced apart from each other between the first circuit board 110 and the second circuit board 120.

According to an embodiment of the present invention, a first layer 180 and a second layer 190 are sequentially disposed between a pad 112 of the first circuit board 110 and the solder ball 130 in a direction from the pad 112 to the solder ball 130. That is, the first layer 180 is disposed on the pad 112 between the pad 112 of the first circuit board 110 and the solder ball 130, and the second layer 190 is disposed on the first layer 180 between the first layer 180 and the solder ball 130.

In this case, the pad 112, the first layer 180, the second layer 190, and the solder ball 130 have different compositions.

As described above, the pad 112 includes a metal having electrical conductivity. Accordingly, in the present specification, the pad 112 may be referred to as a metal pad. For example, the pad 112 may include copper (Cu).

The second layer 190 and the solder ball 130 include tin (Sn).

Accordingly, the first layer 180 is an alloy layer including a metal included in the pad 112 and tin (Sn) included in the second layer 190. When the pad 112 includes Cu, the first layer 180 may be an alloy layer including Cu and Sn. Hereinafter, an example in which the pad 112 includes Cu will be described.

The first layer 180 is a layer formed when the pad 112 of the first circuit board 110 and the second layer 190 are melted during a reflow process of bonding the pad 112 of the first circuit board 110 and the solder ball 130 and may be referred to as an inter-metal compound (IMC) layer.

According to an embodiment of the present invention, a thickness of the first layer 180 may be in a range of 0.1 μm to 2 μm, preferably 0.2 μm to 1.8 μm, or more preferably 0.3 μm to 1.6 μm. The strength of the first layer 180 is lower than that of the second layer 190 and the solder ball 130. Accordingly, the thicker the first layer 180, the greater the possibility of cracks occurring inside the first layer 180 and at an interface of the first layer 180. In particular, when the thickness of the first layer 180 exceeds 2 μm the possibility of cracks occurring in the first layer 180 due to external shock such as thermal shock or vibrations increases.

According to an embodiment of the present invention, the pad 112 may include Cu, and the solder ball 130 may be a SnAgCu-based solder ball including tin (Sn), silver (Ag), and Cu. For example, the solder ball 130 may include Sn_{3.0}Ag_{0.5}Cu. When the solder ball 130 is a SnAgCu-based solder, the solder ball 130 may have higher soldering performance and thermal fatigue resistance characteristics than a SnPb-based solder. However, a SnAgCu-based solder is more expensive than a SnPb-based solder. Since the SnAgCu-based solder has a high melting point of 40° C. or more, an IMC layer may grow quickly to be thick. Thus, a ball grid array package may be degraded, and the reliability thereof may be reduced.

According to an embodiment of the present invention, a SnBi-based solder material having a lower melting point than the solder ball 130 is applied between the pad 112 and the solder ball 130 which is a SnAgCu-based solder, and then a reflow process is performed.

Accordingly, the thickness of the first layer 180 which is an IMC layer may be adjusted to be in a range of 0.1 μm to 2 μm, and the solder ball 130 which is a SnAgCu-based solder reacts with the SnBi-based solder material to generate the second layer 190 including Sn, Ag, Cu, and Bi. The second layer 190 including Sn, Ag, Cu, and Bi may easily absorb or alleviate shock as compared to the SnBi-based solder material that is brittle and thus may have high reliability.

When the pad 112 includes Cu, the solder ball 130 includes Sn_{3.0}Ag_{0.5}Cu, the solder ball 130 is coated with a solder material of Sn58Bi, and then a reflow process is performed, the first layer 180 having a composition of Cu₆Sn₅ and the second layer 190 having a composition of Sn₃₀Bi₂Ag_{0.2}Cu may be formed.

Referring to FIGS. 10A and 10B, the second layer 190 according to the embodiment of the present invention includes a section in which, from an interface between the first layer 180 and the second layer 190 to an interface between the second layer 190 and the solder ball 130, a content of Bi increases and then decreases, and a content of Cu decreases and then increases. In this way, when the first layer 180 and the second layer 190 are formed through a reaction between the pad 112, a solder material of SnBi, and the solder ball 130, a content of Bi and a content of Cu in the second layer 190 may gradually change. Accordingly, since an interface between the first layer 180 and the second layer 190 and an interface between the second layer 160 and the solder ball 130 are not clearly distinguished, and a coefficient of thermal expansion gradually changes in the pad 112, the first layer 180, the second layer 190, and the solder ball 130, a warpage of a ball grid array package due to thermal shock can be prevented, and the possibility of cracks occurring along the interface can also be reduced.

According to an embodiment of the present invention, a section including a highest point P1 of the content of Bi in the second layer 190 may coincide with a section including a lowest point P2 of the content of Cu in the second layer 190. Here, the coincidence between the section including the highest point P1 of the content of BI and the section including the lowest point P2 of the content of Cu may mean that a distance between the highest point P1 of the content of Bi and the lowest point P2 of the content of Cu is within 20%, preferably within 10%, or more preferably within 5% of a thickness of the second layer 190. Here, the distance between the highest point P1 of the content of Bi and the lowest point P2 of the content of Cu may be a distance in a direction from the first circuit board 110 to the second circuit board 120. Accordingly, the second layer 190 may have a stable composition to have excellent brittleness and may be safe from external shock.

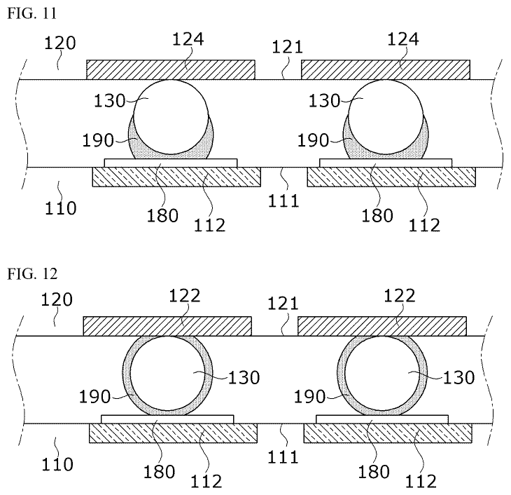

FIG. 11 is a cross-sectional view of a ball grid array package according to yet another embodiment of the present invention. FIG. 12 is a cross-sectional view of the ball grid array package according to yet another embodiment of the present invention. Redundant descriptions of the same contents as those described with reference to FIGS. 9 to 11 are omitted.

Referring to FIGS. 11 and 12, a first layer 180 and a second layer 190 are sequentially disposed between a pad 112 of a first circuit board 110 and a solder ball 130 in a direction from the pad 112 to the solder ball 130. That is, the first layer 180 is disposed on the pad 112 between the pad 112 of the first circuit board 110 and the solder ball 130, and the second layer 190 is disposed on the first layer 180 between the first layer 180 and the solder ball 130.

In this case, as shown in FIG. 11, the second layer 190 may be disposed between the first layer 180 and the solder ball 130 and may extend from a lower surface of the solder ball 130 toward the second circuit board 120 along a side surface of the solder ball 130. That is, the solder ball 130 which is a SnAgCu-based solder may react with a SnBi-based solder material so that the second layer 190 including Sn, Ag, Cu, and Bi may extend from the lower surface of the solder ball 130 toward the second circuit board 120 along the side surface of the solder ball 130. Accordingly, the second layer 190 not only may increase the bonding strength between the solder ball 130 and the pad 112, but also may reinforce the side surface of the solder ball 130, thereby minimizing the problem of cracks occurring in the solder ball 130 even when frequent thermal shock or external shock is applied.

Alternatively, as shown in FIG. 12, the second layer 190 may be disposed between the first layer 180 and the solder ball 130 and may be disposed to extend from the lower surface of the solder ball 130 to a lower surface 121 of the second circuit board 120 along the side surface of the solder ball 130. That is, the solder ball 130 which is a SnAgCu-based solder may react with a SnBi-based solder material so that the second layer 190 including Sn, Ag, Cu, and Bi may be disposed to extend from the lower surface of the solder ball 130 to the lower surface 121 of the second circuit board 120 along the side surface of the solder ball 130. Accordingly, the second layer 190 may increase the bonding strength between the solder ball 130 and the pad 112, may reinforce the side surface of the solder ball 130, and also may increase the bonding strength between the solder ball 130 and the lower surface 121 of the second circuit board 120, thereby minimizing the problem of cracks occurring in the solder ball 130 even when frequent thermal shock or external shock are applied.

In this case, the second layer 190 disposed on the side surface of each solder ball 130 may be disposed to be spaced apart from the second layer 190 disposed on the side surface of another adjacent solder ball 130. That is, there may be a gap between the second layer 190 disposed on the side surface of each solder ball 130 and the second layer 190 disposed on the side surface of another adjacent solder ball 130. Accordingly, since the second layer 190 has excellent brittleness as compared to a SnBi-based solder material, the second layer 190 may protect each solder ball 130 from thermal shock or external physical shock without completely filling a space between a plurality of solder balls 130 disposed to be spaced apart from each other.

Although not shown, a bonding agent may be further disposed in at least some areas between the plurality of solder balls 130 disposed to be spaced apart from each other between the first circuit board 110 and the second circuit board 120.

Although not shown, a filling member may be further disposed on the first circuit board 110 along an edge of the second circuit board 120.

The description of the bonding agent and the filling member may be applied in the same manner as the description of the bonding agent 150 and the filling member 170 described with reference to FIGS. 1 to 8.

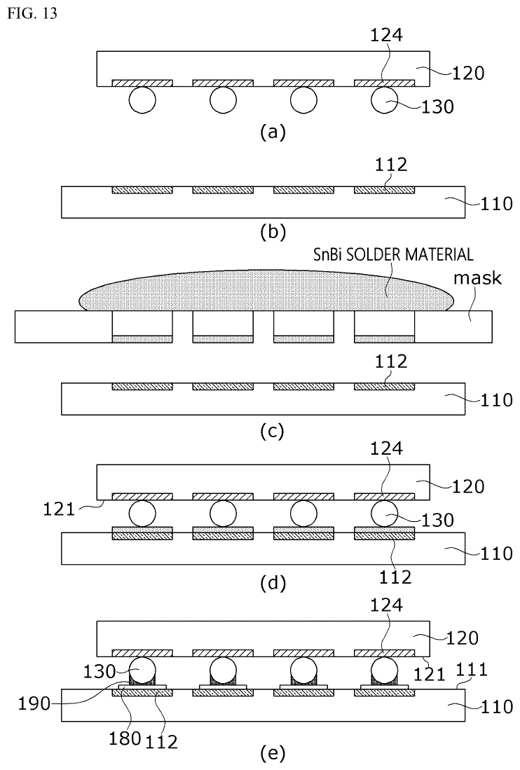

FIG. 13 is a flowchart illustrating a process of manufacturing a ball grid array package according to an embodiment of the present invention.

Referring to FIG. 13A, a second circuit board 120 in which a plurality of solder balls 130 are attached to a lower surface thereof is provided, and referring to FIG. 13B, a first circuit board 110 in which a pad 112 is disposed on an upper surface thereof is provided. As described above, although not shown, an IC chip 140 may be disposed on the upper surface of the second circuit board 120, and the first circuit board 110 may be a single-layer or multi-layer printed circuit board including the pad 112 disposed on an upper surface 111.

Referring to FIG. 13C, the pad 112 of the first circuit board 110 is coated with a SnBi-based solder material. Here, the SnBi-based solder material may be Sn58Bi. The SnBi-based solder material may have a lower melting point than the solder ball 130 has. For example, when the solder ball 130 is a SnAgCu-based solder, the melting point of the solder ball 130 may be about 220° C., and the melting point of the SnBi-based solder material may be about 139° C. The pad 112 of the first circuit board 110 may be coated with the SnBi-based solder material through screen printing, but the present invention is not limited thereto. The pad 112 of the first circuit board 110 may be coated with the SnBi-based solder material through dispensing.

Referring to FIG. 13D, the second circuit board 120 in which the plurality of solder balls 130 are disposed on a lower surface 121 is disposed on the first circuit board 110. In this case, the plurality of solder balls 130 may be disposed to be arranged on the pads 112 of the first circuit board 110. Although not shown, an IC chip 140 may be disposed in advance on an upper surface 122 of the second circuit board 120.

Referring to FIG. 13E, a reflow process is performed. The reflow process may be performed at a temperature that is greater than a melting point of the SnBi-based solder material and the melting point of the solder ball 130. For example, the reflow process may be performed at a temperature that is less than a melting point of a SnBiAgCu-based solder with a novel composition formed through a reaction between a SnBi-based solder material and a SnAgCu-based solder ball 130. For example, the reflow process may be performed at a temperature that is greater than 139° C. and less than 175° C. Accordingly, a second layer 190 including a SnBiAgCu-based solder with a novel composition may be formed through a reaction between the SnBi-based solder material and the SnAgCu-based solder ball 130. In addition, a first layer 180 which is an IMC layer including Cu and Sn may also be formed through a reaction between the pad 112 and a SnBi-based solder material.

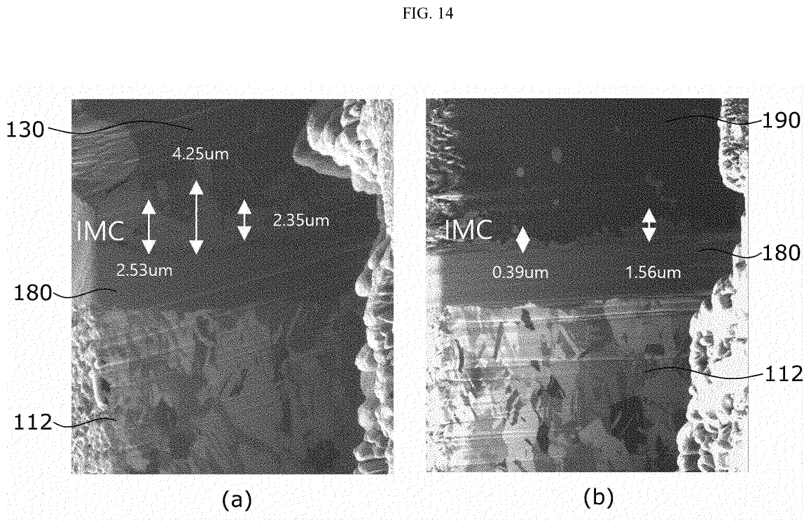

Table 2 shows reliability test results according to comparative examples and an example. FIG. 14 shows cross-sectional images of ball grid array packages according to comparative examples and an example.

According to comparative example 11, a pad 112 of a first circuit board 110 made of Cu and a solder ball made of Sn₃Ag_{0.5}Cu were reflowed under conditions of a temperature of 220° C.

According to comparative example 12, a pad 112 of a first circuit board 110 made of Cu and a solder ball made of Sn58Bi were reflowed under conditions of a temperature of 139° C.

According to example 11, a solder material of Sn58Bi was applied between a pad 112 of a first circuit board 110 made of Cu and a solder ball made of Sn₃Ag_{0.5}Cu and then was reflowed under conditions of a peak temperature of 175° C.

TABLE 2

| | IMC average | Shear | | |
|---|---|---|---|---|
| Experiment | thickness | strength | Drop | Thermal shock |
| number | (μm) | (N) | test | (−40° C. to 125° C.) |
| Comparative | 2.7 | 2.12 | 80 times | 10.00 cycles |
| example 11 | | | | |
| Comparative | 0.5 | 2.6 | 5 times | 1,200 cycles |
| example 12 | | | | |
| Example 11 | 0.6 | 2.3 | 85 times | 1,500 cycles |

FIG. 14A is a cross-sectional image of the ball grid array package manufactured according to comparative example 11, and FIG. 14B is a cross-sectional image of the ball grid array package manufactured according to example 11.

Referring to comparative Example 11 of Table 2 and FIG. 14A, when the pad 112 of the first circuit board 110 made of Cu and the solder ball made of Sn₃Ag_{0.5}Cu are reflowed under conditions of a temperature of 220° C., it can be seen that a thickness of an IMC layer of Cu₆Sn₅ exceed 2 μm, specifically, in a range of 2.35 μm to 4.25 μm. When the thickness of the IMC layer of Cu₆Sn₅ exceeds 2 μm, there is the high possibility of cracks occurring in the IMC layer, along an interface between the pad 112 and the IMC layer, or along an interface between the IMC layer and a solder ball 130.

On the other hand, referring to Example 11 of Table 2 and FIG. 14B, when a Sn58Bi-based solder material is applied between the pad 112 of the first circuit board 110 made of Cu and the solder ball made of Sn₃Ag_{0.5}Cu and then reflowed under conditions of a peak temperature of 175° C., it can be seen that a thickness of an IMC layer of Cu₆Sn₅ is 2 μm or less, specifically, in a range of 0.3 μm to 1.56 μm. When the thickness of the IMC layer of Cu₆Sn₅ is 2 μm or less, the possibility of cracks occurring inside the IMC layer, along an interface between the pad 112 and the IMC layer, or along an interface between the IMC layer and a solder ball 130 may be reduced.

Meanwhile, in comparison between comparative example 12 and example 11, it can be seen that the shear strength of comparative example 12 is higher than that of example 11, but the drop strength of comparative example 12 is very weak. This is because a SnBi-based solder is brittle and thus cannot cushion or absorb shock.

That is, according to example 11, it can be seen that example 11 has higher shear strength and higher drop strength than Comparative Example 11 and has significantly higher drop strength than comparative example 12.

In addition, in a thermal shock test performed under conditions in which a temperature changes from −40° C. to 80° C. and a dwell time is 10 minutes, it can be seen that a structure according to example 11 obtains higher reliability results than structures according to comparative examples 11 and 12.

According to an embodiment of the present invention, since a solder ball 130 includes a SnAuCu-based solder, while the solder ball 130 has excellent solderability and high heat fatigue resistance characteristics, a low-temperature reflow process is possible, thereby preventing a warpage due to a high-temperature reflow process.

In addition, according to an embodiment of the present invention, a thickness of an IMC layer between a pad 112 and a solder ball 130 can be minimized, thereby preventing cracks in the IMC layer, at an interface between the pad and the IMC layer, or at an interface between the IMC layer and the solder ball.

In addition, according to an embodiment of the present invention, since a surface of a solder ball 130 is surrounded by a SnBiAgCu-based solder layer, a ball grid array package having high shear strength, high drop strength, and improved reliability against thermal shock can be obtained.

In addition, according to an embodiment of the present invention, reliability due to thermal shock can be increased without an underfill process for filling a space between a plurality of solder balls, thereby reducing a manufacturing process and a time.

Although the present invention has been described with reference to exemplary embodiments, it will be understood by those skilled in the art that various modifications and changes can be made in the present invention without departing from the spirit and scope of the present invention as defined in the appended claims.

1.-10. (canceled)

11. A ball grid array package comprising:
a first circuit board;
a second circuit board disposed on the first circuit board;
a first solder ball and a second solder ball disposed to be spaced apart from each other between the first circuit board and the second circuit board; and
a bonding agent disposed along side surfaces of the first solder ball and the second solder ball from an upper surface of the first circuit board to a lower surface of the second circuit board between the first circuit board and the second circuit board,
wherein a channel area surrounded by the bonding agent is formed between the first circuit board and the second circuit board, and
wherein a minimum thickness of the bonding agent on the first circuit board is greater than a minimum thickness of the bonding agent on the second circuit board.

12. The ball grid array package of claim 11, wherein a horizontal thickness of the bonding agent on a side surface of the first solder ball or the second solder ball on a center line between the first circuit board and the second circuit board is in a range of 10% to 50% of at least one of a diameter of the first solder ball and a diameter of the second solder ball.

13. The ball grid array package of claim 11, wherein a horizontal thickness of the bonding agent on a side surface of the first solder ball or the second solder ball on a center line between the first circuit board and the second circuit board is in a range of 5 μm to 20 μm.

14. The ball grid array package of claim 11, wherein an area of the bonding agent in contact with the upper surface of the first circuit board is greater than an area of the bonding agent in contact with the lower surface of the second circuit board.

15. The ball grid array package of claim 11, wherein an area of the channel area is in a range of 30% to 70% of an area of a separation area between the first solder ball and the second solder ball.

16. The ball grid array package of claim 11, wherein an area of the channel area is in a range of 50% to 70% of an area of a separation area between the first solder ball and the second solder ball.

17. The ball grid array package of claim 11, wherein a maximum width of the channel area is at least 50% of a diameter of at least one of the first solder ball and the second solder ball.

18. The ball grid array package of claim 11, wherein:
the bonding agent includes a first bonding agent disposed along a first side surface of the first solder ball from the upper surface of the first circuit board to the lower surface of the second circuit board and a second bonding agent disposed along a second side surface of the second solder ball from the upper surface of the first circuit board to the lower surface of the second circuit board, and
the first side surface of the first solder ball and the second side surface of the second solder ball are disposed to face each other.

19. The ball grid array package of claim 18, wherein the first bonding agent and the second bonding agent meet each other on the upper surface of the first circuit board, and do not meet each other on the lower surface of the second circuit board.

20. The ball grid array package of claim 18, wherein at least one of the first bonding agent and the second bonding agent includes an area in which a horizontal thickness decreases and then increases again in a direction from the first circuit board to the second circuit board.

21. The ball grid array package of claim 11, wherein the bonding agent includes an epoxy resin, a curing agent, and an inorganic filler.

22. The ball grid array package of claim 21, wherein the curing agent includes an anhydride and acid.

23. The ball grid array package of claim 21, wherein the curing agent includes an anhydride and abietic acid.

24. The ball grid array package of claim 21, wherein the curing agent includes hexahydromethylphthalic anhydride and rosin.

25. The ball grid array package of claim 24, wherein the curing agent further includes pentanedioic acid.

26. The ball grid array package of claim 21, wherein the epoxy resin includes a naphthalene-based epoxy resin.

27. The ball grid array package of claim 11, wherein the first solder ball is connected by a pad of the first circuit board and a pad of the second circuit board.

28. The ball grid array package of claim 27, wherein the pad of the first circuit board and the pad of the second circuit board are disposed to be engraved.

29. A ball grid array package comprising:
a first circuit board;
a second circuit board disposed on the first circuit board;
a first solder ball and a second solder ball disposed to be spaced apart from each other between the first circuit board and the second circuit board; and
a bonding agent disposed along side surfaces of the first solder ball and the second solder ball from an upper surface of the first circuit board to a lower surface of the second circuit board between the first circuit board and the second circuit board,
wherein a channel area surrounded by the bonding agent is formed between the first circuit board and the second circuit board, and
wherein the bonding agent includes an epoxy resin, a curing agent having a flux function, and an inorganic filler.

30. The ball grid array package of claim 29, wherein the curing agent includes an anhydride and abietic acid.
